(19) United States
(12) Patent Application Publication
(10) Pub. No.: US 2024/0204025 A1
(43) Pub. Date: Jun. 20, 2024

(54) IMAGE SENSOR

(71) Applicant: Samsung Electronics Co., Ltd., Suwon-si (KR)

(72) Inventors: Byeongtaek BAE, Suwon-si (KR); Seunghwi YOO, Suwon-si (KR); Kooktae KIM, Suwon-si (KR); Jingyun KIM, Suwon-si (KR)

(73) Assignee: Samsung Electronics Co., Ltd., Suwon-si (KR)

(21) Appl. No.: 18/526,404

(22) Filed: Dec. 1, 2023

(30) Foreign Application Priority Data
Dec. 20, 2022 (KR) 10-2022-0179732

(51) Int. Cl. H01L 27/146

(52) U.S. Cl. CPC H01L 27/1463; H01L 27/14683

(57) ABSTRACT

Provided is an image sensor including a substrate including a first photoelectric conversion region, and an isolation region arranged in the substrate vertically from the first surface and defining the first photoelectric conversion region, wherein the isolation region includes a first semiconductor pattern conformally covering an inner wall of a trench, an insulating film conformally covering an inner wall of the first semiconductor pattern, a second semiconductor pattern conformally covering an inner wall of a lower portion of the insulating film, and a conductive pattern covering an inner wall of an upper portion of the insulating film and an uppermost surface and an inner wall of the second semiconductor pattern, wherein a vertical distance from the first surface to the uppermost surface of the first semiconductor pattern is substantially the same as a vertical distance from the first surface to the uppermost surface of the conductive pattern.

### CROSS-REFERENCE TO RELATED APPLICATION

This application is based on and claims priority under 35 U.S.C. § 119 to Korean Patent Application No. 10-2022-0179732, filed on Dec. 20, 2022, in the Korean Intellectual Property Office, the entire contents of which are incorporated herein by reference.

### BACKGROUND

The inventive concepts described herein relate to an image sensor, and more specifically, to an image sensor capable of providing a clear image signal.

The image sensor converts an optical image into an electrical signal. Common image sensors include Charge Coupled Device (CCD) type image sensors and CMOS type image sensors (CIS). These image sensors are equipped with a plurality of pixels arranged in the form of a two-dimensional matrix, and each pixel outputs an image signal from light energy. Each of the plurality of pixels accumulates photoelectric charges corresponding to the amount of light incident through a photoelectric conversion element and outputs a pixel signal based on the accumulated photoelectric charges. Recently, as the degree of integration of image sensors increases, the size of pixels decreases and the size of components of pixel circuits also decreases.

### SUMMARY

The inventive concepts described herein provide a more reliable image sensor according to some example embodiments by forming a more uniform conductor overlapping the entire interface of a photoelectric conversion region.

Although the inventive concepts described herein relate to the above-mentioned task, the inventive concepts are not limited thereto, and other tasks not mentioned may be clearly understood by those of ordinary skill in the art from the following description.

According to some example embodiments, there is provided an image sensor including a substrate having a first surface and a second surface opposite to each other and including a first photoelectric conversion region, and an isolation region in the substrate that extends vertically from the first surface and defines the first photoelectric conversion region, wherein the isolation region includes a trench, a first semiconductor pattern conformally covering an inner wall of the trench, an insulating film conformally covering an inner wall of the first semiconductor pattern, a second semiconductor pattern conformally covering an inner wall of a lower portion of the insulating film, and a conductive pattern covering an inner wall of an upper portion of the insulating film and an uppermost surface and an inner wall of the second semiconductor pattern and configured to receive a negative bias voltage, wherein a vertical distance from the first surface to the uppermost surface of the first semiconductor pattern is substantially the same as a vertical distance from the first surface to the uppermost surface of the conductive pattern.

According to some example embodiments, there is provided an image sensor including a substrate having a first surface and a second surface opposite to each other and including a first photoelectric conversion region, and an isolation region in the substrate that extends vertically from the first surface and defines the first photoelectric conversion region, wherein the isolation region includes a trench, a first semiconductor pattern conformally covering an inner wall of the trench, an insulating film conformally covering an inner wall of the first semiconductor pattern, and a second semiconductor pattern covering at least a portion of an inner wall of the insulating film and receiving a negative bias voltage applied thereto, wherein a vertical distance from the first surface to an uppermost surface of the first semiconductor pattern is substantially the same as a vertical distance from the first surface to an uppermost surface of the second semiconductor pattern.

According to some example embodiments, there is provided an image sensor including a substrate having a first surface and a second surface opposite to each other and including a plurality of photoelectric conversion regions in a lattice structure, an isolation region in the substrate that extends vertically from the first surface and defines the first photoelectric conversion region, a second photoelectric conversion region spaced apart in a first direction parallel to the second surface, a third photoelectric conversion region spaced apart in a diagonal direction with respect to the first direction, an insulating layer between the first photoelectric conversion region and the second photoelectric conversion region and including silicon oxide or silicon nitride, a conductive layer between the first photoelectric conversion region and the third photoelectric conversion region and including an undoped polysilicon layer, and a color filter and a micro lens on an upper portion of the second surface, wherein the isolation region includes a trench, a first semiconductor pattern conformally covering an inner wall of the trench, an insulating film conformally covering an inner wall of the first semiconductor pattern, and a second semiconductor pattern covering the inner wall of the trench, and a second semiconductor pattern covering an inner wall of a lower portion of the insulating film and including polysilicon doped with boron (B), and a conductive pattern comprising undoped polysilicon, covering an inner wall of an upper portion of the insulating film and an uppermost and an inner wall of the second semiconductor pattern, and receiving a negative bias voltage applied thereto, wherein a vertical distance from the first surface to an uppermost surface of the first semiconductor pattern is substantially the same as a vertical distance from the first surface to an uppermost surface of the conductive pattern, and a vertical distance from the first surface to an uppermost surface of the second semiconductor pattern is greater than a vertical distance from the first surface to the uppermost surface of the conductive pattern.

### BRIEF DESCRIPTION OF THE DRAWINGS

The inventive concepts will be more clearly understood from the following detailed description of some example embodiments taken in conjunction with the accompanying drawings in which:

FIG. 1 is a circuit diagram of an image sensor according to some example embodiments of the inventive concepts;

FIG. 2 is a plan view illustrating an image sensor according to some example embodiments of the inventive concepts;

FIG. 3 is a cross-sectional view taken along line I-I′ of FIG. 2;

FIG. 4 is an enlarged cross-sectional view of a pixel array region of an image sensor according to some example embodiments of the inventive concepts;

FIGS. 5 and 6 are plan views of a pixel array region of an image sensor according to some example embodiments of the inventive concepts;

FIG. 7 is a cross-sectional view of a pixel array region of the image sensor shown in FIGS. 5 and 6;

FIGS. 8A to 8F are cross-sectional views illustrating a part of a manufacturing process of the image sensor illustrated in FIG. 7 according to some example embodiments of the inventive concepts;

FIGS. 9 and 10 are plan views of a pixel array region of an image sensor according to some example embodiments of the inventive concepts;

FIG. 11 is a cross-sectional view of a pixel array region of the image sensor shown in FIGS. 9 and 10; and

FIGS. 12A to 12F are cross-sectional views illustrating a part of a manufacturing process of the image sensor illustrated in FIG. 11 according to some example embodiments of the inventive concepts.

### DETAILED DESCRIPTION

Hereinafter, some example embodiments of the inventive concepts will be described in detail with reference to the accompanying drawings. However, the inventive concepts are not limited to the example embodiments described below, and may be embodied in various other forms. The following embodiments are simply provided to sufficiently convey the scope of the inventive concept to those skilled in the art, rather than to ensure that the inventive concept is completely completed.

Accordingly, the drawings and description are to be regarded as illustrative in nature and not restrictive. For example, unless expressly indicated otherwise, the sizes of elements may be exaggerated for clarity and/or convenience of explanation.

As used herein, the singular forms “a” and “an” are intended to include the plural forms as well, unless expressly indicated otherwise. Likewise, the terms “the” and similar instruction terms may correspond to both singular and plural.

Although elements throughout the following description may be referred to as first, second or the like, as used herein, these terms are used to distinguish one element or component from another element or component and should not be interpreted to limit the described example embodiments unless expressly indicated otherwise.

As used herein, what is referred to as “above” or “on” may include not only directly in a contact manner but also in a non-contact manner.

Moreover, elements may be listed as comprising one or more various materials throughout the following description, but the inventive concepts described herein should not be interpreted as limited to the disclosed materials unless expressly indicated otherwise. For example, one of ordinary skill in the art will appreciate that materials with similar functional properties to those described herein may be used in addition to, or in lieu of, specific materials described herein.

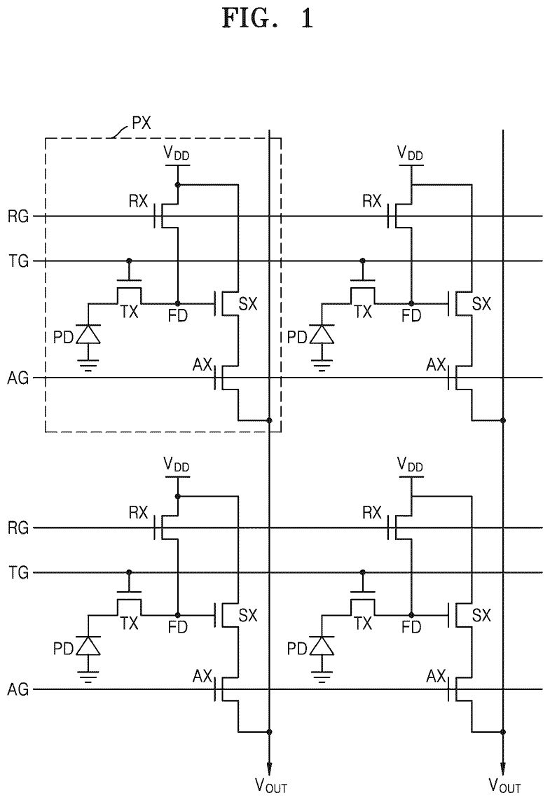

FIG. 1 is a circuit diagram of an image sensor according to some example embodiments of the inventive concepts.

Referring to FIG. 1, each of unit pixel region PX of the image sensor may include a photoelectric conversion region PD, a transmission transistor TX, a source follower transistor SX, a reset transistor RX, and a selection transistor AX. Each of the transmission transistor TX, the source follower transistor SX, the reset transistor RX, and the selection transistor AX may include a transmission gate TG, a reset gate RG, and a selection gate AG.

The photoelectric conversion region PD may be a photodiode including an n-type impurity region and a p-type impurity region. The floating diffusion region FD may function as a drain of the transmission transistor TX. The floating diffusion region FD may function as a source of the reset transistor RX. The source follower transistor SX may be connected to the selection transistor AX.

The operation of the image sensor will be described below with reference to FIG. 1. When light is blocked from the photoelectric conversion region PD, a power voltage V_{DD} is applied to the drain of the reset transistor RX and the drain of the source follower transistor SX, and the reset transistor RX is turned on to release charges remaining in the floating diffusion region FD. Then, when the reset transistor RX is turned off and light from outside of the image sensor 1 is incident into the photoelectric conversion region PD, an electron-hole pair is generated in the photoelectric conversion region PD. Holes are accumulated in the p-type impurity region of the photoelectric conversion region PD, and electrons are accumulated in the n-type impurity region. When the transmission transistor TX is turned on, charges such as electrons and holes are transferred to the floating diffusion region FD and are accumulated. The gate bias of the source follower transistor SX changes based on, or in proportion to, the accumulated amount of charge, resulting in a change in the source potential of the source follower transistor SX. When the selection transistor AX is turned on, a signal caused by electric charges is read through a column line.

A wiring line may be electrically connected to at least one of the transmission gate TG, the reset gate RG, and/or the selection gate AG. The wiring line may be configured to apply a power voltage V_{DD} to a drain of the reset transistor RX and/or a drain of the source follower transistor SX. The wiring line may include a column line connected to the selection transistor AX. The wiring line may be wirings to be described later.

Although a unit pixel region including one photoelectric conversion region PD and four transistors TX, RX, AX, and SX is illustrated in FIG. 1, example embodiments according to the inventive concepts are not limited thereto. For example, according to some example embodiments, multiple pixels may be provided, and the reset transistor RX, the source follower transistor SX, and/or the selection transistor AX may be shared by neighboring pixels. Accordingly, the degree of integration of the image sensor may be improved.

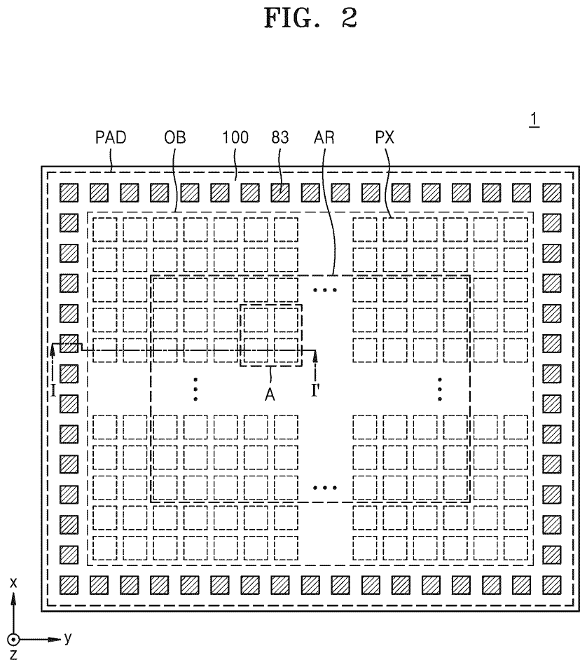

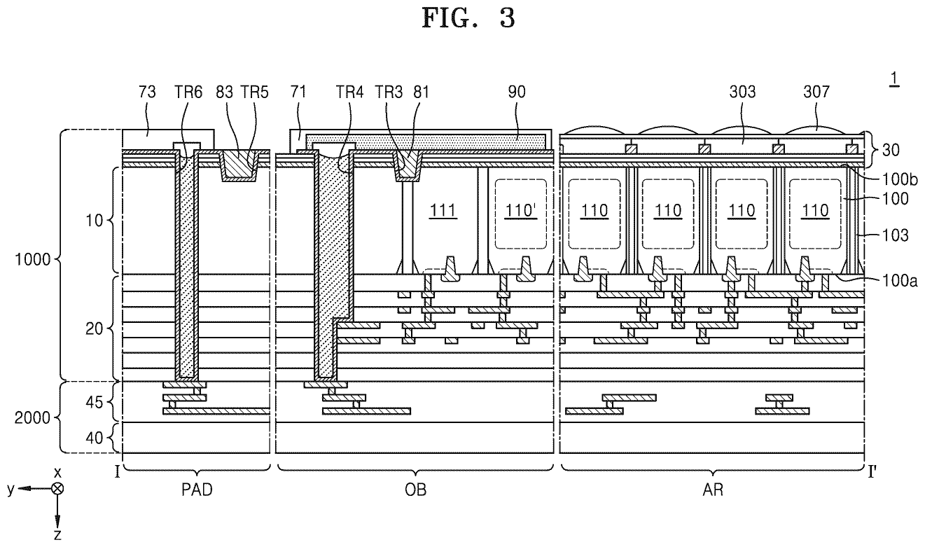

FIG. 2 is a plan view illustrating an image sensor according to some example embodiments of the inventive concepts, and FIG. 3 is a cross-sectional view taken along line I-I′ of FIG. 2.

Referring to FIGS. 2 and 3, an image sensor 1 may include a sensor chip 1000 and a logic chip 2000. The sensor chip 1000 may include a photoelectric conversion layer 10, a first wiring layer 20, and a light transmission layer 30. The photoelectric conversion layer 10 may include a substrate 100, a device isolation pattern 103, and photoelectric conversion regions 110 which may be provided in the substrate 100. Light incident from outside of the image sensor 1 may be converted into an electrical signal in the photoelectric conversion regions 110.

The substrate 100 may include a pixel array region AR, an optical black region OB, and a pad region PAD from a plan view. The pixel array region AR may be arranged at a center portion of the substrate 100 in a plan view. The pixel array region AR may include a plurality of unit pixel regions PX. The plurality of unit pixel regions PX may output a photoelectric signal from incident light. The unit pixel regions PX may form columns and rows, and may be two-dimensionally arranged. The columns may be parallel to a first horizontal direction (x direction). The rows may be parallel to a second horizontal direction (y direction). In some example embodiments, the first horizontal direction (x direction) may be parallel to a first surface 100a of the substrate 100. In some example embodiments, the second horizontal direction (y direction) may be parallel to the first surface 100a of the substrate 100 and may be different from the first horizontal direction (x direction). For example, the second horizontal direction (y direction) may be substantially perpendicular to the first horizontal direction (x direction). In some example embodiments, the third direction (z direction) may be substantially perpendicular to the first surface 100a of the substrate 100.

The pad region PAD may be provided at an edge portion of the substrate 100 and may surround the pixel array region AR in a plan view. Second pad terminals 83 may be provided on the pad region PAD. The second pad terminals 83 may output electrical signals generated in the unit pixel regions PX to devices outside of the image sensor 1. Alternatively, or in addition to outputting electrical signals, an external electrical signal or voltage may be transmitted to the unit pixel regions PX through the second pad terminals 83. Since the pad region PAD is arranged at the edge portion of the substrate 100, the second pad terminals 83 may be easily connected to devices outside of the image sensor 1.

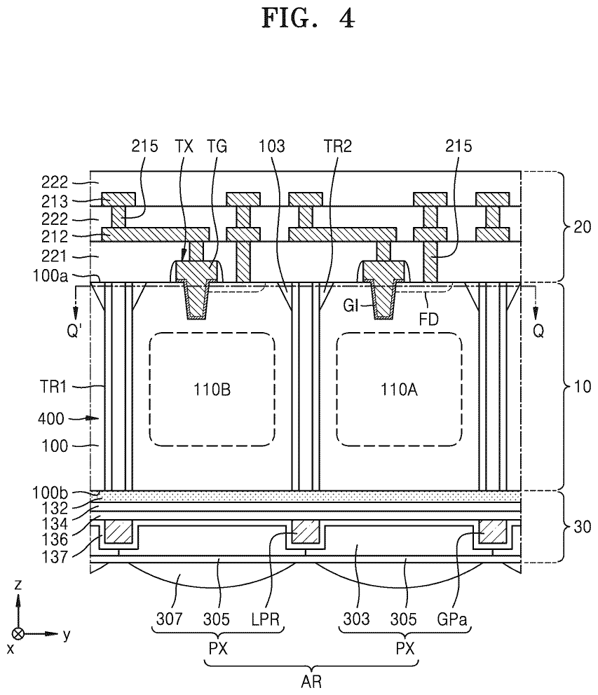

The optical black region OB may be arranged between the pixel array region AR and the pad region PAD of the substrate 100. The optical black region OB may surround the pixel array region AR in a plan view. The optical black region OB may include a plurality of dummy regions 111. The signals generated in the dummy regions 111 may then be used as information for removing process noise. Hereinafter, the pixel array region AR of the image sensor 1 will be described in more detail with reference to FIG. 4 according to some example embodiments.

FIG. 4 is an enlarged cross-sectional view of a pixel array region of an image sensor according to some example embodiments of the inventive concepts.

Referring to FIG. 4, an image sensor according to some example embodiments of the inventive concepts may include a photoelectric conversion layer 10, a first wiring layer 20, and/or a light transmission layer 30. The photoelectric conversion layer 10 may include a substrate 100, an isolation region 400, and/or a device isolation pattern 103.

The substrate 100 may have a first surface 100a (e.g., a front surface) and a second surface 100b (e.g., a rear surface) facing each other. Light may be incident on the second surface 100b of the substrate 100. The first wiring layer 20 may be arranged on the first surface 100a of the substrate 100, and the light transmission layer 30 may be arranged on the second surface 100b of the substrate 100. The substrate 100 may be a semiconductor substrate and/or a silicon on insulator (SOI) substrate. The semiconductor substrate may include, for example, a silicon substrate, a germanium substrate, and/or a silicon-germanium substrate. The substrate 100 may include first conductivity type impurities. For example, the first conductivity type impurities may include p-type impurities such as aluminum (Al), boron (B), indium (In), and/or gallium (Ga).

The substrate 100 may include photoelectric conversion regions 110A and 110B (e.g., 110 of FIG. 3). The photoelectric conversion regions 110A and 110B may be provided in the unit pixel regions PX in the substrate 100. The photoelectric conversion regions 110A and 110B may perform the same function and role as the photoelectric conversion region PD of FIG. 1. The photoelectric conversion regions 110A and 110B may be regions doped with impurities of a second conductivity type in the substrate 100. The impurities of the second conductivity type may have a conductivity type opposite to the impurities of the first conductivity type. The second conductivity type impurities may include n-type impurities such as phosphorus, arsenic, bismuth, and/or antimony. The photoelectric conversion regions 110A and 110B may be adjacent to a first surface 100a of the substrate 100. In some example embodiments, the photoelectric conversion regions 110A and 110B may be arranged closer to the first surface 100a than the second surface 100b. For example, each of the photoelectric conversion regions 110A and 110B may include a first region having a first thickness that is adjacent to the first surface 100a and a second region having a second thickness less than the first thickness that is adjacent to the second surface 100b. An impurity concentration difference between the first region and the second region of the photoelectric conversion regions 110A and 110B may be provided. Accordingly, the photoelectric conversion regions 110A and 110B may have a potential slope, e.g. a potential gradient, between the first surface 100a and the second surface 100b of the substrate 100 but is not limited thereto. In some example embodiments, the photoelectric conversion regions 110A and 110B may not have a potential slope, e.g. a potential gradient, between the first surface 100a and the second surface 100b of the substrate 100 and may have, for example, a uniform potential.

The substrate 100 and the photoelectric conversion regions 110A and 110B may constitute a photodiode. For example, the photodiode may be constructed by the p-n junction of the substrate 100 of the first conductivity type and the photoelectric conversion regions 110A and 110B of the second conductivity type. The photoelectric conversion regions 110A and 110B constituting the photodiode may generate and accumulate photo charges in proportion to the intensity of incident light.

As shown in FIG. 4, the isolation region 400 may be provided in the substrate 100, and unit pixel regions PX may be defined. For example, the isolation region 400 may be provided between the unit pixel regions PX of the substrate 100. From a plan view, the isolation region 400 may have a lattice structure. From a plan view, the isolation region 400 may completely surround each of the unit pixel regions PX. The isolation region 400 may be provided in a first trench TR1, and the first trench TR1 may be recessed from the first surface 100a of the substrate 100. The isolation region 400 may extend from the first surface 100a of the substrate 100 toward the second surface 100b of the substrate 100. The isolation region 400 may be a deep trench isolation layer. The isolation region 400 may pass through the substrate 100. The vertical height of the isolation region 400 may be substantially the same as the vertical thickness of the substrate 100. In some example embodiments, the width of the isolation region 400 may gradually decrease from the first surface 100a to the second surface 100b of the substrate 100 but is not limited thereto. A more detailed description of the isolation region 400 will be provided later.

According to some example embodiments, the device isolation pattern 103 may be provided in the substrate 100. For example, the device isolation pattern 103 may be provided in the second trench TR2, and the second trench TR2 may be recessed from the first surface 100a of the substrate 100. A bottom surface of the device isolation pattern 103 may be provided in the substrate 100. The width of the device isolation pattern 103 may gradually decrease from the first surface 100a to the second surface 100b of the substrate 100 but is not limited thereto. At least a part of the device isolation pattern 103 may be arranged on the upper sidewall of the isolation region 400, and may be connected to the upper sidewall of the isolation region 400. The depth of the device isolation pattern 103 may be less than the depth of the isolation region 400. The device isolation pattern 103 may include, for example, silicon oxide, silicon nitride, and/or silicon oxynitride.

The transmission transistors TX described above with reference to FIG. 1 may be provided on the first surface 100a of the substrate 100. The transmission transistors TX may be electrically connected to the photoelectric conversion regions 110A and 110B, respectively.

According to some example embodiments, the first wiring layer 20 may include wiring insulating layers 221 and 222, wirings 212 and 213, and vias 215. The wiring insulating layers 221 and 222 may include a first wiring insulating layer 221 and a second wiring insulating layer 222. The first wiring insulating layer 221 may cover the first surface 100a of the substrate 100. The first wiring insulating layer 221 may be provided between the wiring 212 and the first surface 100a of the substrate 100. The second wiring insulating layers 222 may be stacked on the first wiring insulating layer 221. The first and second wiring insulating layers 221 and 222 may include a non-conductive material. For example, the first and second wiring insulating layers 221 and 222 may include silicon-based insulating materials such as silicon oxide, silicon nitride, and/or silicon oxynitride.

The wirings 212 and 213 may be provided on the first wiring insulating layer 221. More specifically, the wirings 212 and 213 may be arranged in the second wiring insulating layers 222 stacked on the first surface 100a of the substrate 100. The wirings 212 and 213 may be vertically connected to the transmission transistors TX through the vias 215. The electrical signals converted in the photoelectric conversion regions 110A and 110B may be signal-processed in the first wiring layer 20. In some example embodiments, the arrangement of the wirings 212 and 213 may be arranged regardless of the arrangement of the photoelectric conversion regions 110A and 110B. For example, the wirings 212 and 213 may cross upper portions of the photoelectric conversion regions 110A and 110B. The wirings 212 and 213 may include first wirings 212 and second wirings 213. The first and second wirings 212 and 213 and the vias 215 may include a metal material, for example, copper (Cu) or tungsten (W).

The light transmission layer 30 may include color filters 303 and microlenses 307. The light transmission layer 30 may collect and filter light incident from outside of the image sensor 1 to provide light to the photoelectric conversion layer 10.

In some example embodiments, color filters 303 and microlenses 307 may be provided on the second surface 100b of the substrate 100. The color filters 303 may be arranged on the unit pixel regions PX, respectively. The microlenses 307 may each be arranged on the color filters 303, respectively. A rear insulating film 132 and first auxiliary insulating films 134 and 136 may be arranged between the second surface 100b of the substrate 100 and the color filters 303. The rear insulating film 132 may cover the second surface 100b of the substrate 100. The rear insulating film 132 may be in contact with the second surface 100b of the substrate 100. For example, the rear insulating film 132 may include at least one of a bottom antireflective coating (hereinafter, referred to as BARC) layer, a fixed charge layer, an adhesive layer, and/or a protective layer. The rear insulating film 132 may function as the bottom antireflective layer and the reflection of light may be reduced or prevented so that light incident on the second surface 100b of the substrate 100 may reach the photoelectric conversion regions 110. In some example embodiments, by reducing or preventing the reflection of light via the rear insulating film 132, light incident on the second surface 100b of the substrate 100 may smoothly reach the photoelectric conversion region. The rear insulating film 132 and the first auxiliary insulating films 134 and 136 may include a metal oxide (e.g., aluminum oxide or hafnium oxide) and/or a silicon-based insulating material (e.g., silicon oxide or silicon nitride). A second auxiliary insulating film 305 may be arranged between the color filters 303 and the microlenses 307.

The color filters 303 may include primary color filters. The color filters 303 may include first to third color filters having different colors. For example, the first to third color filters may include color filters of green, red, and blue, respectively, but are not limited thereto. For example, the first to third color filters may include other colors such as cyan, magenta, and/or yellow, etc. The first to third color filters may be arranged in a Bayer pattern manner.

The microlenses 307 may be arranged on bottom surfaces of the color filters 303, respectively. The microlenses 307 may vertically overlap the photoelectric conversion regions 110A and 110B, respectively. Although not shown in the drawings, in some example embodiments the microlenses 307 may be connected to each other. The microlenses 307 may be transparent and may transmit light. The microlenses 307 may have a convex shape to concentrate light incident on the unit pixel regions PX but are not limited thereto. For example, the microlenses 307 may have other shapes suitable for concentrating light. The microlenses 307 may include an organic material. For example, the microlenses 307 may include a photoresist material or a thermosetting resin.

The image sensor may further include a protective layer 137. The protective layer 137 may be placed between a first auxiliary insulating film 136 and each of the color filters 303, and between the grit pattern GRa and each of the color filters 303. The protective layer 137 may include an insulating material such as a high dielectric material. For example, the protective layer 137 may include aluminum oxide or hafnium oxide.

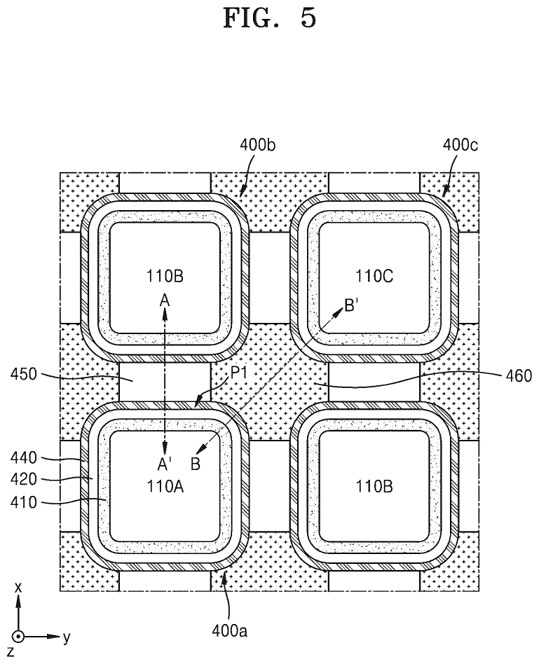

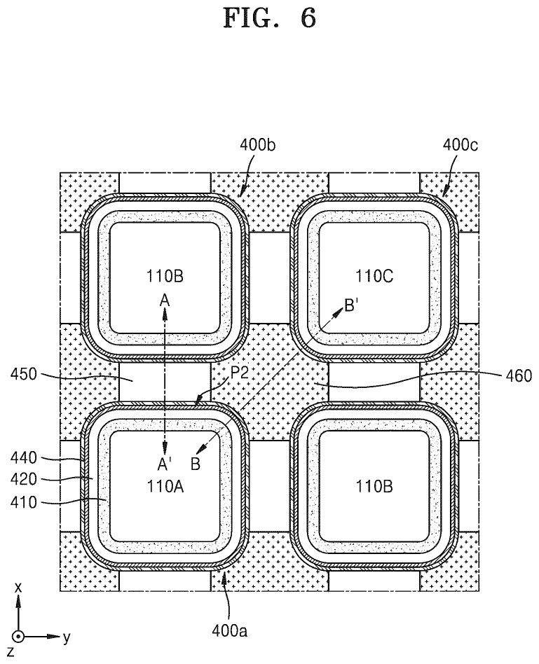

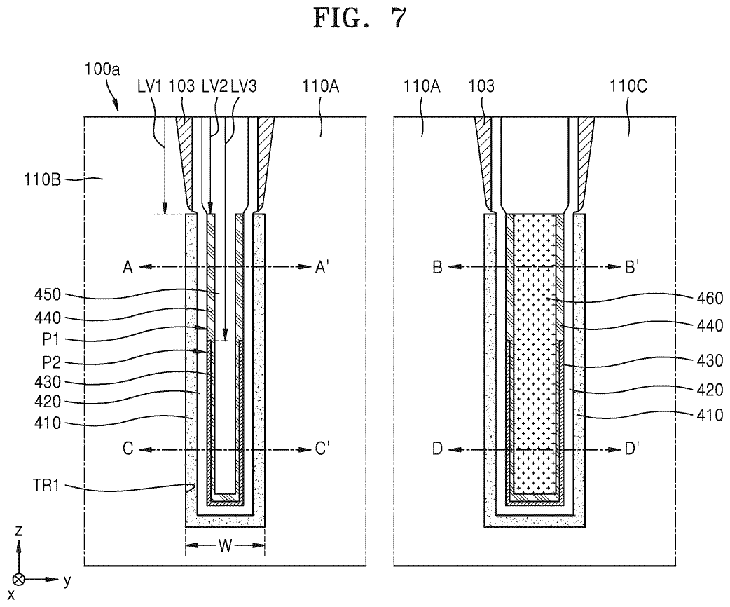

FIGS. 5 and 6 are plan views of a pixel array region AR of an image sensor according to some example embodiments of the inventive concepts, and FIG. 7 is a cross-sectional view of a pixel array region AR of the image sensor shown in FIGS. 5 and 6 according to some example embodiments. Specifically, FIG. 5 is a plan view illustrating an upper part of the isolation region 400 according to some example embodiments along Q-Q′ of FIG. 4, and FIG. 6 is a plan view illustrating a lower part of the isolation region 400 according to some example embodiments.

Referring to FIGS. 5 to 7, a plurality of photoelectric conversion regions 110A, 110B, and 110C may be arranged in a lattice structure in the photoelectric conversion layer 10. Based on a first photoelectric conversion region 110A, a second photoelectric conversion region 110B may be arranged in a first horizontal direction (x direction) parallel to the first surface 100a of the substrate 100 and a second horizontal direction (y direction) perpendicular to the first horizontal direction. In addition, a third photoelectric conversion region 110C may be arranged in a diagonal direction of the first photoelectric conversion region 110A.

As shown in FIG. 5, a first isolation region 400a may be arranged in the substrate 100 in a vertical direction from the first surface 100a, and the first photoelectric conversion region 110A may be defined. The first isolation region 400a may include a first semiconductor pattern 410 that may conformally cover an inner wall of a first trench TR1 formed inside the photoelectric conversion layer 10. The first semiconductor pattern 410 may be a crystalline semiconductor material, for example, polycrystalline silicon doped with impurities. The impurities may include n-type or p-type impurities, and may include, for example, boron (B). The first semiconductor pattern 410 may face the interfaces of the plurality of photoelectric conversion regions 110A, 110B, and 110C located on the outer wall of the first trench TR1. Trapped electrons may be generated at interfaces of the plurality of photoelectric conversion regions 110A, 110B, and 110C. In this case, the first semiconductor pattern 410 including p-type impurities includes holes, so that electrons trapped across the interfaces of the plurality of photoelectric conversion regions 110A, 110B, and 110C may not diffuse into the plurality of photoelectric conversion regions 110A, 110B, and 110C. When trapped electrons diffuse into the plurality of photoelectric conversion regions 110A, 110B, and 110C, dark current may occur, which may weaken the reliability of the image sensor or otherwise reduce performance of the image sensor.

According to some example embodiments, the first isolation region 400a may include an insulating film 420 that may conformally cover an inner wall of the first semiconductor pattern 410. The insulating film 420 may include a non-conductive material. For example, the insulating film 420 may include a silicon oxide layer, a silicon oxynitride layer, and/or a silicon nitride layer.

The first isolation region 400a may include a second semiconductor pattern 430 that may conformally cover an inner wall of a lower portion of the insulating film 420. The second semiconductor pattern 430 may include a conductive material. For example, the second semiconductor pattern 430 may include polysilicon doped with boron (B). A negative bias voltage may be applied to the second semiconductor pattern 430, thereby increasing the concentration of holes in the first semiconductor pattern 410. However, when the width W of the first trench TR1 is large, the exposed surface region of the second semiconductor pattern 430 may be large in the process of forming the second semiconductor pattern 430. Therefore, a significant portion of the second semiconductor pattern 430 is etched, and a vertical distance LV3 to a top surface of the second semiconductor pattern 430 from the first surface 100a may be greater than a vertical distance LV1 to a top surface of the first semiconductor pattern 410 from the first surface 100a. The second semiconductor pattern 430 may be placed between the insulating film 420 and a conductive pattern 440 which is to be described later.

The first isolation region 400a may include the conductive pattern 440 which may cover an inner wall of an upper portion of the insulating film 420 and an uppermost surface and an inner wall of the second semiconductor pattern 430, and receives a negative bias voltage applied thereto. The conductive pattern 440 may include undoped polysilicon. In this case, the thickness of the conductive pattern 440 may be about 10 nanometers or less. The conductive pattern 440 may be formed to extend vertically from the first surface 100a to the second surface 100b. A vertical distance LV2 from the first surface 100a to an uppermost surface of the first semiconductor pattern 410 may be substantially the same as a vertical distance LV1 from the first surface 100a to an uppermost surface of the conductive pattern 440. In other words, a side surface of the conductive pattern 440 may overlap at least a portion of a side surface of the first semiconductor pattern 410.

The conductive pattern 440 may be formed to cover one side surface and a top surface of the second semiconductor pattern 430. Therefore, the conductive pattern 440 may include a first region P1 which may cover an inner wall of an upper portion of the insulating film 420 and a second region P2 which may cover an uppermost surface and an inner wall of the second semiconductor pattern 430. The second semiconductor pattern 430 may not be placed between the first region P1 and the first semiconductor pattern 410 in a direction perpendicular to the direction in which the first trench TR1 is formed. In other words, a vertical distance LV3 from the first surface 100a to an uppermost surface of the second semiconductor pattern 430 may be greater than a vertical distance LV2 from the first surface 100a to the uppermost surface of the conductive pattern 440. The conductive pattern 440 may include a conductive material such as undoped polysilicon, and a negative bias voltage may be applied thereto. The conductive pattern 440 to which the negative bias voltage is applied may increase the concentration of holes in which the first semiconductor pattern 410 has a relatively positive charge in the second region P2.

According to some example embodiments, a thickness of the first region P1 of the conductive pattern 440 may be greater than a thickness of the second region P2 of the conductive pattern 440. Here, the thickness of the first region P1 of the conductive pattern 440 may be substantially the same as the sum of the thickness of the second region P2 of the conductive pattern 440 and the thickness of the second semiconductor pattern 43.

In addition, since the conductive pattern 440 to which the negative bias voltage is applied may be electrically connected to the second semiconductor pattern 430, a negative voltage may be applied to the second semiconductor pattern 430 in contact with the conductive pattern 440. Therefore, the second semiconductor pattern 430 to which the negative bias voltage is applied may increase the concentration of holes in which the first semiconductor pattern 410 has a relatively positive charge in the first region P1. As a result, since the conductive pattern 440 having conductivity is formed to overlap the entire side surface of the first semiconductor pattern 410, electrons generated throughout the interfaces of the plurality of photoelectric conversion regions 110A, 110B, and 110C do not diffuse in the plurality of photoelectric conversion regions 110A, 110B, and 110C, thereby reducing or preventing generation of dark current.

According to some example embodiments, the conductive pattern 440 may include polysilicon formed in a process having relatively good step coverage. For example, the conductive pattern 440 may include, but is not limited to, polysilicon formed by an atomic layer deposition (ALD) or chemical vapor deposition (CVD) process.

Referring back to FIG. 7 together with FIGS. 5 and 6, the image sensor 1 may include a second photoelectric conversion region 110B which may be spaced apart from the first photoelectric conversion region 110A in a first horizontal direction (x direction) parallel to the second surface 100b, and a second isolation region 400b defining the second photoelectric conversion region 110B. An insulating layer 450 may be arranged between the first isolation region 400a and the second isolation region 400b. The insulating layer 450 may include silicon oxide and/or silicon nitride. The insulating layer 450 may be buried in the conductive pattern 440. The insulating layer 450 may include an insulating material such as silicon oxide, silicon nitride, silicon oxynitride, and/or a low-k dielectric material.

In addition, the image sensor 1 may include a third photoelectric conversion region 110C which may be spaced apart from the first photoelectric conversion region 110A diagonally to the first horizontal direction (x direction) and a third isolation region 400c defining the third photoelectric conversion region 110C. A conductive layer 460 may be arranged between the first isolation region 400a and the third isolation region 400c. The conductive layer 460 may include an undoped polysilicon layer. The conductive layer 460 may be electrically connected to the conductive pattern 440 included in each of the first isolation region 400a, the second isolation region 400b, and the third isolation region 400c. Accordingly, the conductive layer 460 may be electrically connected to the second semiconductor pattern 430 and electrically connected to the conductive pattern 440. The undoped polysilicon layer included in the conductive layer 460 may have relatively high resistance, but may have a low enough resistance to be electrically connected to the conductive pattern 440 or the second semiconductor pattern 430.

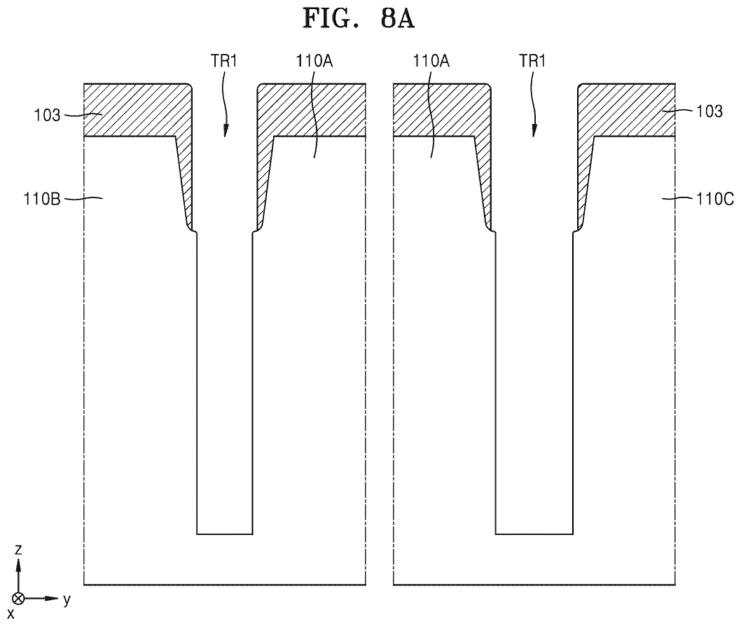

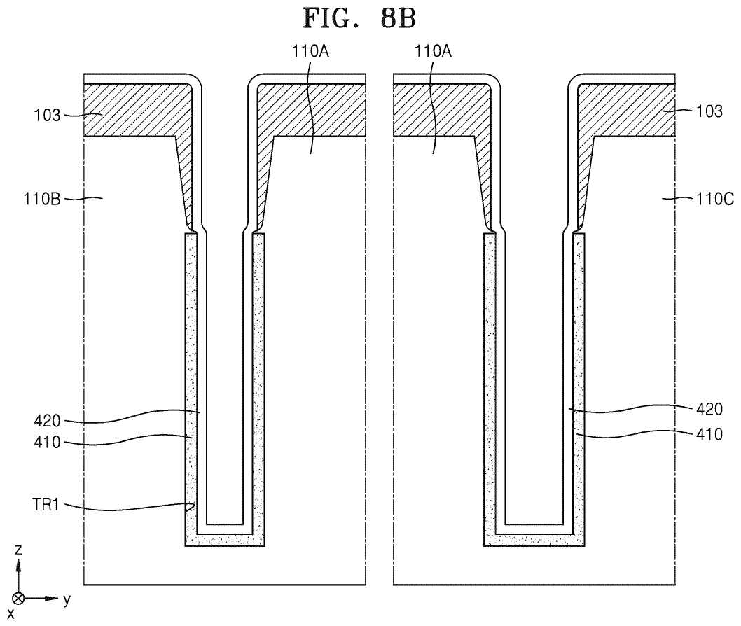

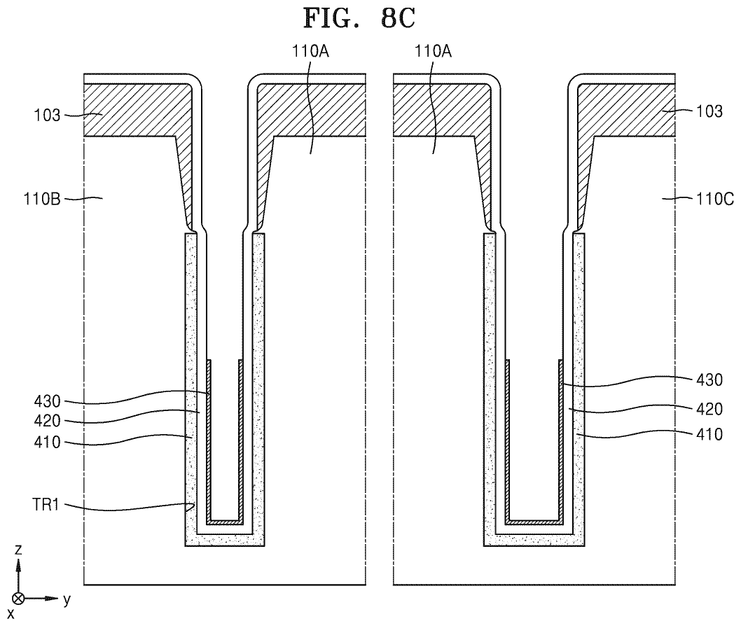

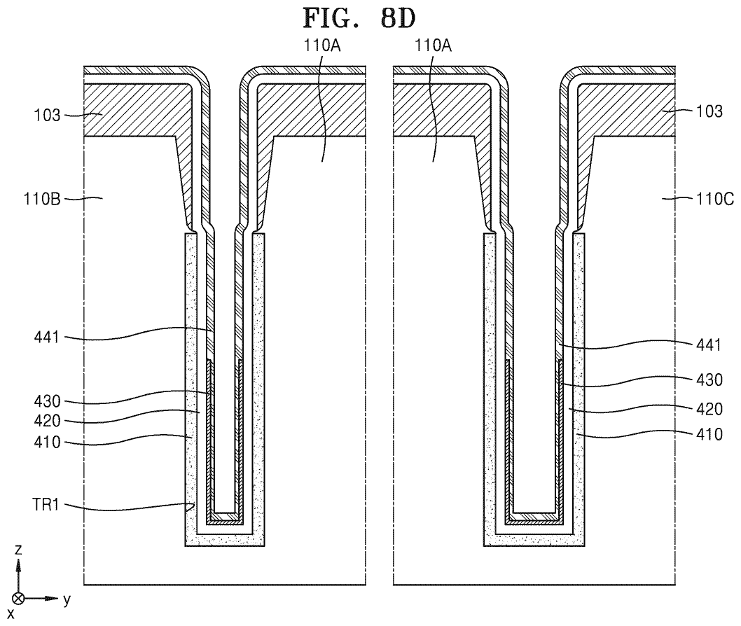

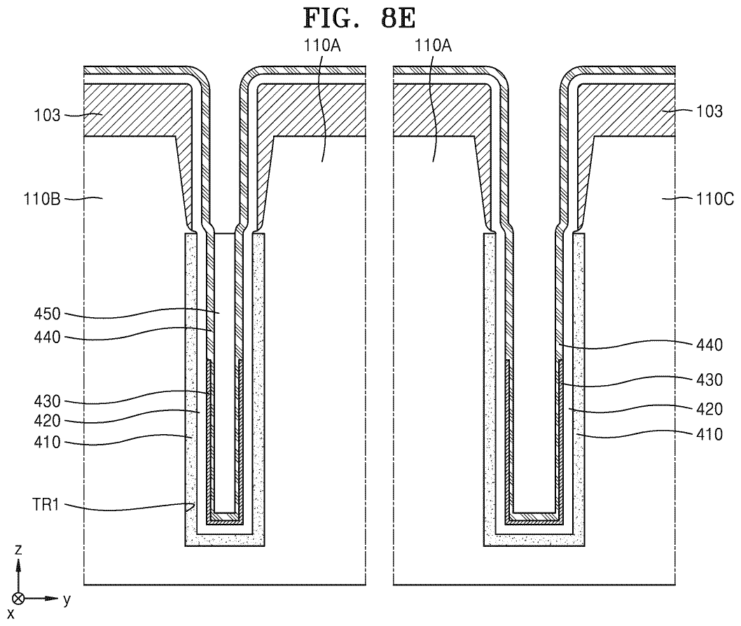

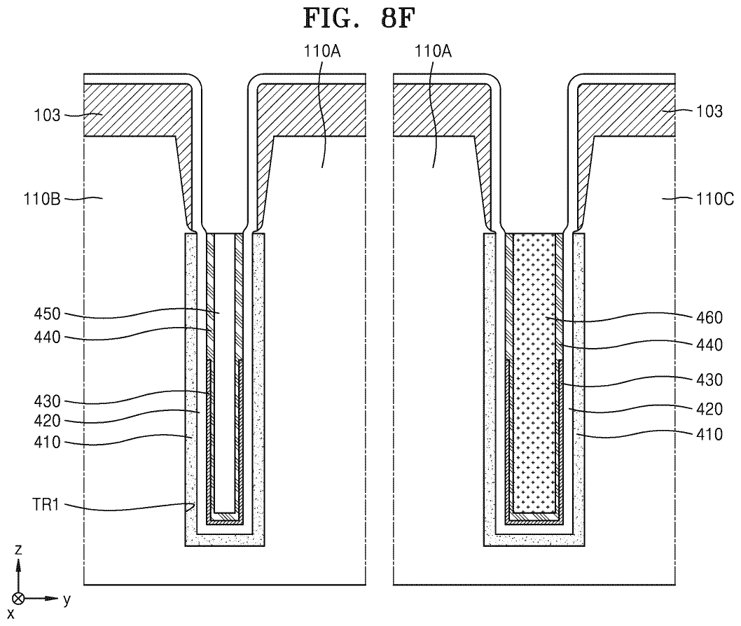

FIGS. 8A to 8F are cross-sectional views illustrating a part of a manufacturing process of the image sensor illustrated in FIG. 7 according to some example embodiments.

Referring to FIG. 8A, a device isolation pattern 103 may be formed on the plurality of photoelectric conversion regions 110A, 110B, and 110C. A portion of the device isolation pattern 103 may penetrate the plurality of photoelectric conversion regions 110A, 110B, and 110C. The device isolation pattern 103 may include, for example, silicon oxide, silicon nitride, and/or silicon oxynitride. A first trench TR1 may be formed by recessing a part of a device isolation pattern 103 that has dug into the plurality of photoelectric conversion regions 110A, 110B, and 110C and each of the plurality of photoelectric conversion regions 110A, 110B, and 110C.

Referring to FIG. 8B, the first semiconductor pattern 410 may be formed which may conformally cover a portion of an inner wall of the first trench TR1. Thereafter, an insulating film 420 that may conformally cover the inner wall of the first semiconductor pattern 410 and the inner wall and the top surface of the device isolation pattern 103 may be formed. For example, the first semiconductor pattern 410 and the insulating film 420 may include, but is not limited to, polysilicon formed by an ALD or CVD process. The first semiconductor pattern 410 may be a crystalline semiconductor material, for example, polycrystalline silicon doped with impurities. The impurities may include n-type or p-type impurities, and may include, for example, boron (B).

Referring to FIG. 8C, the second semiconductor pattern 430 may then be formed which may conformally cover at least a portion of an inner wall of the insulating film 420. The second semiconductor pattern 430 may include, but is not limited to, polysilicon formed by an ALD or CVD process. The second semiconductor pattern 430 may include polysilicon doped with boron (B). The vertical distance to the uppermost surface of the second semiconductor pattern 430 from the first surface 100a of the substrate 100 may be greater than the vertical distance to the uppermost surface of the first semiconductor pattern 410 from the first surface 100a. Accordingly, a side surface of the second semiconductor pattern 430 may overlap a part of a side surface of the first semiconductor pattern 410.

Referring to FIGS. 8D and 8E, a conductive layer 441 may be formed that may conformally cover an inner wall and a top surface of the second semiconductor pattern 430, and an inner wall and a top surface of the insulating film 420. The conductive layer 441 may include undoped polysilicon. The conductive layer 441 may include, for example, polysilicon formed by an ALD and/or CVD process but is not limited thereto. After forming the conductive layer 441, the conductive layer 441 may be arranged between the first photoelectric conversion region 110A and the second photoelectric conversion region 110B to form an insulating layer 450 that buries the inside of the conductive layer 441. The insulating layer 450 may include a non-conductive material. For example, the insulating layer 450 may include silicon-based insulating materials such as silicon oxide, silicon nitride, and/or silicon oxynitride.

Referring to FIG. 8F, a conductive layer 460 may be arranged between the first photoelectric conversion region 110A and the third photoelectric conversion region 110C to bury the inside of the conductive layer 441. The vertical distance to the uppermost surface of the conductive layer 460 from the first surface 100a of the substrate 100 may be substantially the same as the vertical distance of the uppermost surface of the first semiconductor pattern 410 from the first surface 100a. After the conductive layer 460 is formed, a part of the conductive layer 441 may be etched to form the conductive pattern 440. The process of etching the conductive layer 441 may be a process using an etching selectivity. For example, the conductive layer 441 may include undoped polysilicon, and the insulating layer 450 may include silicon oxide or the like. In this case, the etching speed of the undoped polysilicon in the process of etching the conductive layer 441 may be faster than the etching speed of the silicon oxide. Therefore, the conductive layer 441 placed inside the insulating layer 450 and the insulating film 420 may be etched relatively slowly, and the conductive layer 441 exposed to the outside may be etched relatively quickly. Eventually, most of the conductive layer 441 exposed to the outside is etched, and a conductive pattern 440 placed inside the insulating layer 450 and the insulating film 420 is formed.

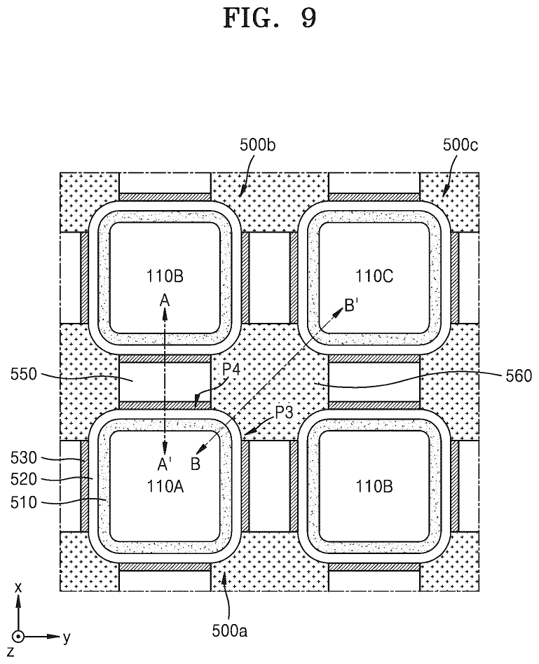

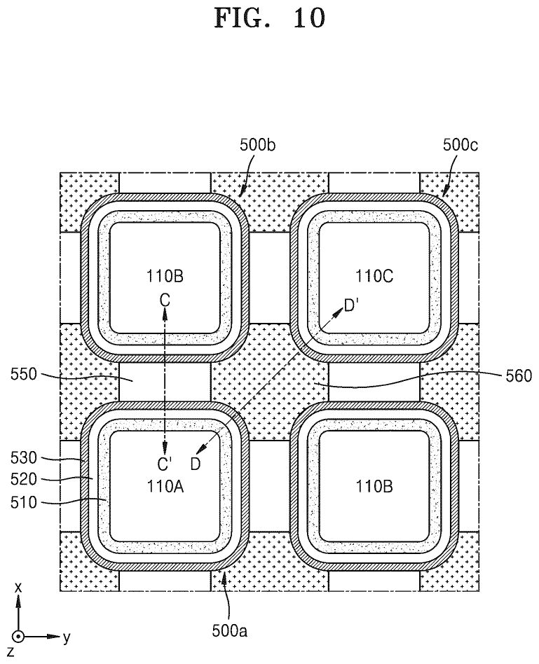

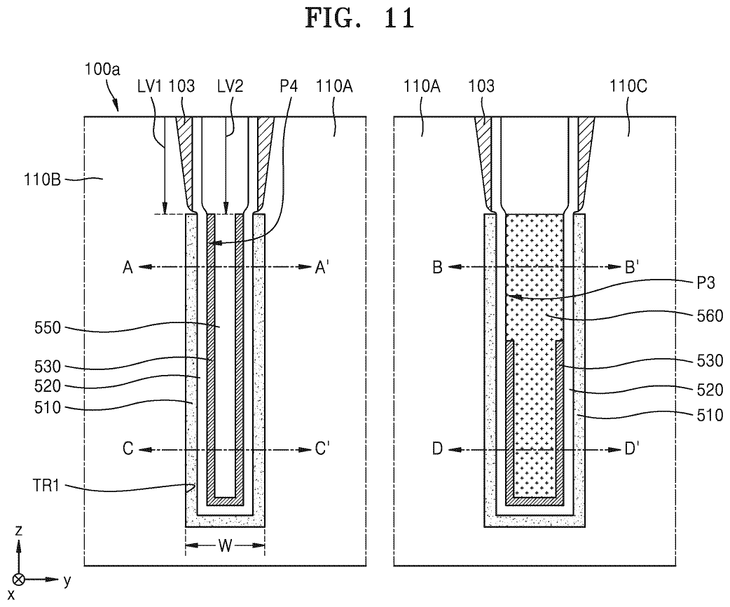

FIGS. 9 and 10 are plan views of a pixel array region of an image sensor according to some example embodiments of the inventive concepts. FIG. 11 is a cross-sectional view of a pixel array region of the image sensor shown in FIGS. 9 and 10. Specifically, FIG. 9 is a plan view illustrating an upper portion of the isolation region 500 according to some example embodiments, and FIG. 10 is a plan view illustrating a lower portion of the isolation region 500 according to some example embodiments. The components of FIGS. 9 to 11 may be the same as the components shown in FIGS. 5 to 7 and may perform the same roles or may be formed of the same materials as described with reference to FIGS. 5 to 7. Accordingly, descriptions of the same components of FIGS. 9 to 11 as those shown in FIGS. 5 to 7 will be omitted or simplified.

Hereinafter, the operation and function of FIGS. 9 to 11 will be described with reference to FIG. 4 together. Referring to FIGS. 9 to 11, the plurality of photoelectric conversion regions 110A, 110B, and 110C may be arranged in a lattice structure in the photoelectric conversion layer 10. Based on the first photoelectric conversion region 110A, the second photoelectric conversion region 110B may be arranged in a first horizontal direction (x direction) parallel to the first surface 100a of the substrate 100 and a second horizontal direction (y direction) perpendicular to the first horizontal direction. In addition, the third photoelectric conversion region 110C may be arranged in a diagonal direction of the first photoelectric conversion region 110A.

As shown in FIG. 9, the first isolation region 500a is arranged in the substrate 100 in a vertical direction from the first surface 100a, and the first photoelectric conversion region 110A may be defined. The first isolation region 500a may include a first semiconductor pattern 510 that may conformally cover the inner wall of the first trench TR1 formed inside the photoelectric conversion layer 10. The first semiconductor pattern 510 shown in FIGS. 9 to 11 may be substantially the same component as the first semiconductor pattern 410 shown in FIGS. 5 to 7. The first semiconductor pattern 510 may face the interfaces of the plurality of photoelectric conversion regions 110A, 110B, and 110C located on the outer wall of the first trench TR1. Trapped electrons may be generated at interfaces of the plurality of photoelectric conversion regions 110A, 110B, and 110C. In this case, the first semiconductor pattern 510 including p-type impurities includes holes, so that electrons trapped across the interfaces of the plurality of photoelectric conversion regions 110A, 110B, and 110C may not diffuse into the plurality of photoelectric conversion regions 110A, 110B, and 110C. When trapped electrons diffuse into the plurality of photoelectric conversion regions 110A, 110B, and 110C, dark current may occur, which may weaken the reliability or otherwise degrade the performance of the image sensor.

According to some example embodiments, the first isolation region 500a may include an insulating film 520 that may conformally cover an inner wall of the first semiconductor pattern 510. The insulating film 520 illustrated in FIGS. 9 to 11 may be substantially the same component as the insulating layer 450 illustrated in FIGS. 5 to 7.

The first isolation region 500a may include the second semiconductor pattern 530 that may conformally cover at least a portion of an inner wall of the insulating film 520. The second semiconductor pattern 530 illustrated in FIGS. 9 to 11 may be different from the second semiconductor pattern 530 illustrated in FIGS. 5 to 7. Specifically, the vertical distance from the first surface 100a to the uppermost surface of the second semiconductor pattern 530 may be substantially the same as the vertical distance from the first surface 100a to the uppermost surface of the first semiconductor pattern 510. The second semiconductor pattern 530 may include a conductive material. For example, the second semiconductor pattern 530 may include polysilicon doped with boron (B). A negative bias voltage may be applied to the second semiconductor pattern 530, thereby increasing the concentration of holes having a positive charge in the first semiconductor pattern 510. As shown in the drawing on the left side of FIG. 11, the vertical distance to the uppermost surface of the first semiconductor pattern 510 based on the first surface 100a of the substrate 100 and the vertical distance to the uppermost surface of the second semiconductor pattern 530 from the first surface 100a may be substantially the same, the side surfaces of the second semiconductor pattern 530 may overlap most of the side surfaces of the first semiconductor pattern 510. Accordingly, the concentration of the holes in most regions of the first semiconductor pattern 510 may be increased.

As a result, since the second semiconductor pattern 530 having conductivity may be formed to overlap the entire side surface of the first semiconductor pattern 510, electrons generated throughout the interfaces of the plurality of photoelectric conversion regions 110A, 110B, and 110C do not diffuse in the plurality of photoelectric conversion regions 110A, 110B, and 110C, thereby reducing or preventing generation of dark current.

According to some example embodiments, the second semiconductor pattern 530 may include polysilicon formed by a process having relatively good step coverage. For example, the second semiconductor pattern 430 may include, but is not limited to, polysilicon formed by an ALD or CVD process.

Referring back to FIG. 11 together with FIGS. 9 and 10, the image sensor 1 may include a second photoelectric conversion region 110B spaced apart from the first photoelectric conversion region 110A in a first horizontal direction (x direction) parallel to the second surface 100b, and a second isolation region 500b defining the second photoelectric conversion region 110B. An insulating layer 550 may be arranged between a first isolation region 500a and a second isolation region 500b. The insulating layer 550 may include silicon oxide or silicon nitride. The insulating layer 550 may be buried in the second semiconductor pattern 530. The insulating layer 550 may include an insulating material such as silicon oxide, silicon nitride, silicon oxynitride, and/or a low-k dielectric material.

In addition, the image sensor 1 may include a third photoelectric conversion region 110C spaced apart from the first photoelectric conversion region 110A diagonally to the first horizontal direction (x direction) and a third isolation region 500c defining the third photoelectric conversion region 110C. In this case, a conductive layer 560 may be arranged between the first isolation region 500a and the third isolation region 500c. The conductive layer 560 may include an undoped polysilicon layer. The conductive layer 560 may be electrically connected to the second semiconductor pattern 530 included in each of the first isolation region 400a, the second isolation region 400b, and the third isolation region 400c. The undoped polysilicon layer included in the conductive layer 560 may have relatively high resistance, but may have a low enough resistance to be electrically connected to the second semiconductor pattern 530.

The insulating film 520 of the first isolation region 500a may include a third region P3 in contact with at least a part of the conductive layer 560 and a fourth region P4 in contact with at least a part of the second semiconductor pattern 530. As illustrated in FIG. 9, when viewed from a direction perpendicular to the second surface, the third region P3 may correspond to the edge of the insulating film 520.

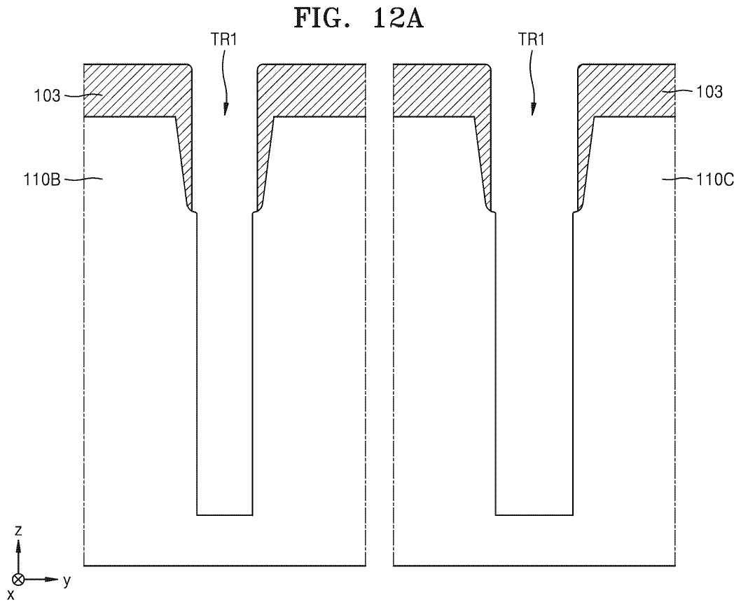

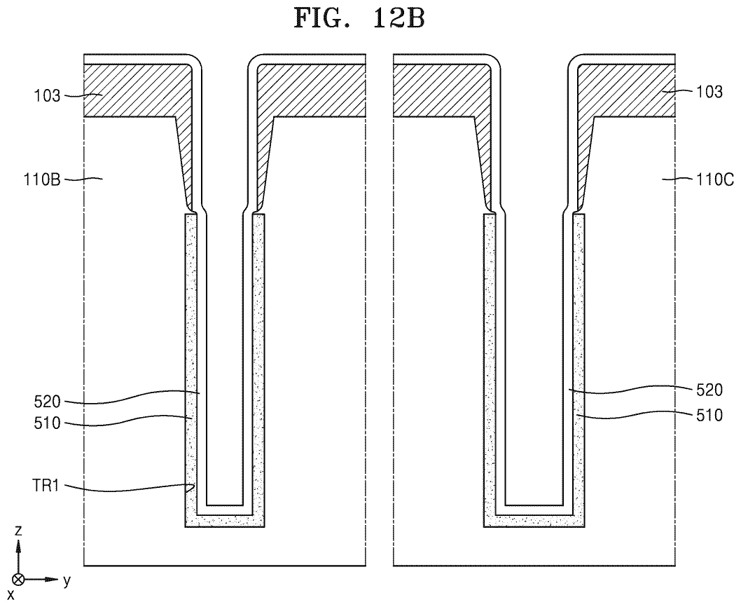

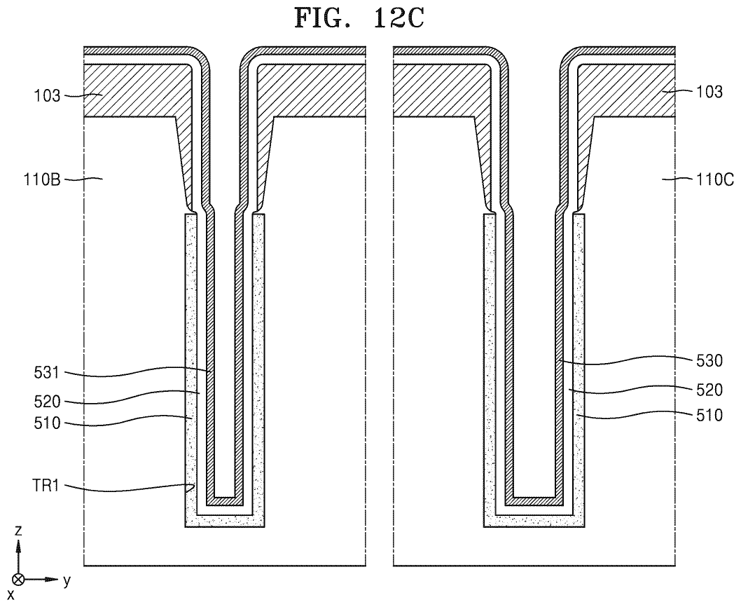

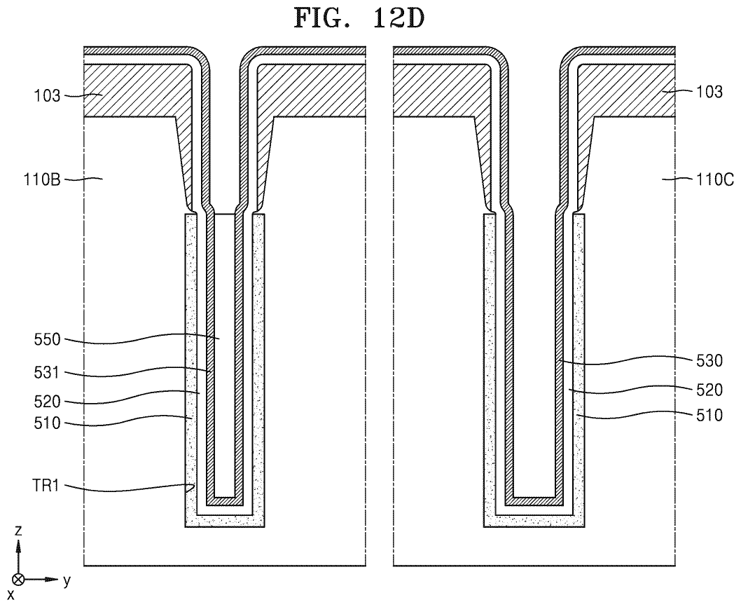

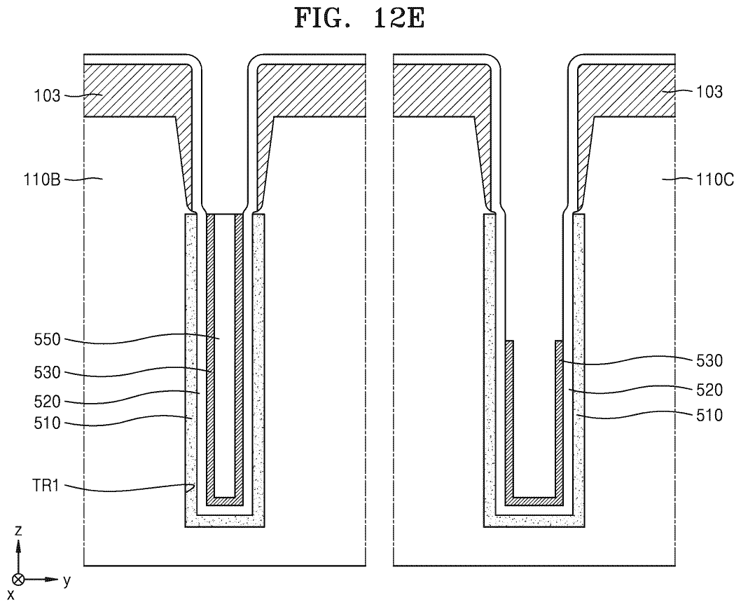

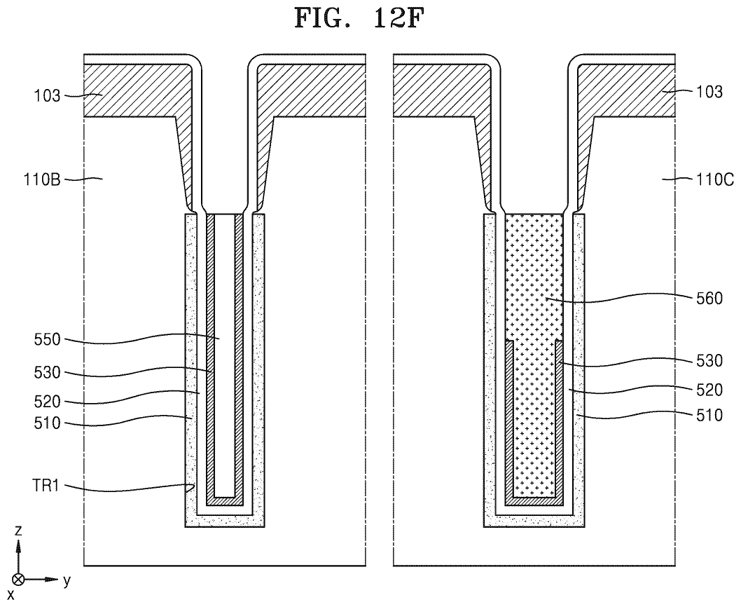

FIGS. 12A to 12F are cross-sectional views illustrating a part of a manufacturing process of the image sensor illustrated in FIG. 11 according to some example embodiments.

Referring to FIG. 12A, a device isolation pattern 103 may be formed on the plurality of photoelectric conversion regions 110A, 110B, and 110C. A portion of the device isolation pattern 103 may penetrate the plurality of photoelectric conversion regions 110A, 110B, and 110C. The device isolation pattern 103 may include, for example, silicon oxide, silicon nitride, and/or silicon oxynitride. A first trench TR1 may be formed by recessing a part of the device isolation pattern 103 that has dug into the plurality of photoelectric conversion regions 110A, 110B, and 110C and each of the plurality of photoelectric conversion regions 110A, 110B, and 110C.

Referring to FIG. 12B, the first semiconductor pattern 510 may be formed that may conformally cover a portion of an inner wall of the first trench TR1. Thereafter, an insulating film 520 that may conformally cover the inner wall of the first semiconductor pattern 510 and the inner wall and the top surface of the device isolation pattern 103 may be formed. For example, the first semiconductor pattern 510 and the insulating film 520 may include, but is not limited to, polysilicon formed by an ALD or CVD process. The first semiconductor pattern 510 may be a crystalline semiconductor material, for example, polycrystalline silicon doped with impurities. The impurities may include n-type or p-type impurities, and may include, for example, boron (B).

Referring to FIG. 12C, a second semiconductor layer 531 may then be formed that may conformally cover an inner wall and a top surface of the insulating film 520. The second semiconductor layer 531 may include, but is not limited to, polysilicon formed by an ALD or CVD process. The second semiconductor layer 531 may include polysilicon doped with boron (B). Unlike the second semiconductor pattern 530 illustrated in FIG. 8C, the second semiconductor layer 531 according to some example embodiments may be formed to cover the entire outer wall of the insulating film 520.

Referring to FIG. 12D, an insulating layer 550 may be formed between the first photoelectric conversion region 110A and the second photoelectric conversion region 110B to bury the inside of the second semiconductor pattern 530. The insulating layer 550 may include a non-conductive material. The insulating layer 550 illustrated in FIGS. 12D and 12E may be substantially the same as the insulating layer 550 illustrated in FIGS. 8E and 8F.

Referring to FIG. 12E, a portion of the second semiconductor layer 531 may be etched to form the second semiconductor pattern 530. The process of etching the second semiconductor layer 531 may be a process using an etching selectivity. For example, the second semiconductor layer 531 may include undoped polysilicon, and the insulating layer 550 may include silicon oxide or the like. The etching speed of the undoped polysilicon in the process of etching the second semiconductor layer 531 may be faster than the etching speed of the silicon oxide. Therefore, the insulating layer 550 and the second semiconductor layer 531 placed inside the insulating film 520 may be etched relatively slowly, and the second semiconductor layer 531 exposed to the outside may be etched relatively quickly. Eventually, most of the second semiconductor layer 531 exposed to the outside is etched, and the insulating layer 550 and the second semiconductor pattern 530 placed inside the insulating film 520 are formed. As shown on the right drawing of FIG. 12E, the second semiconductor layer 531 that is not buried in the insulating layer 550 may be etched in a larger amount than the portions of the insulating layer 550 that are buried. Therefore, the vertical level of the top surface of a portion of the second semiconductor pattern 530, which is not buried in the insulating layer 550 is lower than the vertical level of the top surface of a portion of second semiconductor pattern 530, which is buried in the insulating layer 550.

Referring to FIG. 12F, a conductive layer 560 may be then formed between the first photoelectric conversion region 110A and the third photoelectric conversion region 110C to bury the inside of the second semiconductor pattern 530. The vertical level of the uppermost surface of the conductive layer 560 may be substantially the same as the vertical level of the uppermost surface of the first semiconductor pattern 510.

While some example embodiments according to the inventive concepts have been particularly shown and described with reference to embodiments thereof, it will be understood that various changes in form and details may be made therein without departing from the spirit and scope of the following claims.

What is claimed is:

1. An image sensor comprising:
a substrate having a first surface and a second surface opposite to each other and including a first photoelectric conversion region; and
an isolation region in the substrate that extends vertically from the first surface and defines the first photoelectric conversion region, wherein the isolation region comprises
a trench,
a first semiconductor pattern conformally covering an inner wall of the trench,
an insulating film conformally covering an inner wall of the first semiconductor pattern;
a second semiconductor pattern conformally covering an inner wall of a lower portion of the insulating film, and
a conductive pattern covering an inner wall of an upper portion of the insulating film and an uppermost surface and an inner wall of the second semiconductor pattern and configured to receive a negative bias voltage, wherein
a vertical distance from the first surface to the uppermost surface of the first semiconductor pattern is substantially the same as a vertical distance from the first surface to the uppermost surface of the conductive pattern.

2. The image sensor of claim 1, wherein a vertical distance from the first surface to the uppermost surface of the second semiconductor pattern is greater than a vertical distance from the first surface to the uppermost surface of the conductive pattern.

3. The image sensor of claim 1, wherein the conductive pattern comprises undoped polysilicon.

4. The image sensor of claim 1, wherein the conductive pattern comprises:
a first region covering an inner wall of an upper portion of the insulating film; and
a second region covering an uppermost surface and an inner wall of the second semiconductor pattern, wherein the second semiconductor pattern is not between the first region and the first semiconductor pattern.

5. The image sensor of claim 4, wherein a thickness of the first region of the conductive pattern is greater than a thickness of the second region of the conductive pattern.

6. The image sensor of claim 1, wherein a thickness of a first region of the conductive pattern is substantially the same as a sum of a thickness of a second region of the conductive pattern and a thickness of the second semiconductor pattern.

7. The image sensor of claim 1, further comprising:
a second photoelectric conversion region spaced apart in a first direction parallel to the second surface;
a third photoelectric conversion region spaced apart in a diagonal direction with respect to the first direction; and
an insulating layer between the first photoelectric conversion region and the second photoelectric conversion region and including silicon oxide or silicon nitride.

8. The image sensor of claim 7, further comprising a conductive layer between the first photoelectric conversion region and the third photoelectric conversion region and including undoped polysilicon.

9. The image sensor of claim 8, wherein the conductive layer is electrically connected to the conductive pattern or the second semiconductor pattern.

10. The image sensor of claim 1, wherein the first semiconductor pattern comprises p-type impurities, and the second semiconductor pattern comprises polysilicon doped with boron (B).

11. The image sensor of claim 1, wherein the second semiconductor pattern is between the insulating film and the conductive pattern.

12. An image sensor comprising:
a substrate having a first surface and a second surface opposite to each other and including a first photoelectric conversion region; and
an isolation region in the substrate that extends vertically from the first surface and defines the first photoelectric conversion region, wherein the isolation region comprises:
a trench,
a first semiconductor pattern conformally covering an inner wall of the trench,
an insulating film conformally covering an inner wall of the first semiconductor pattern, and
a second semiconductor pattern covering at least a portion of an inner wall of the insulating film and configured to receive a negative bias voltage, wherein
a vertical distance from the first surface to an uppermost surface of the first semiconductor pattern is substantially the same as a vertical distance from the first surface to an uppermost surface of the second semiconductor pattern.

13. The image sensor of claim 12, further comprising:
a second photoelectric conversion region spaced apart in a first direction parallel to the second surface;
a third photoelectric conversion region spaced apart in a diagonal direction with respect to the first direction; and
an insulating layer between the first photoelectric conversion region and the second photoelectric conversion region and including silicon oxide or silicon nitride.

14. The image sensor of claim 13, further comprising a conductive layer between the first photoelectric conversion region and the third photoelectric conversion region and including undoped polysilicon.

15. The image sensor of claim 14, wherein the insulating film of the isolation region comprises:
a third region in contact with at least a portion of the conductive layer; and
a fourth region in contact with at least a portion of the second semiconductor pattern.

16. The image sensor of claim 15, wherein, when viewed from a direction perpendicular to the second surface, the third region corresponds to a corner portion of the insulating film of the isolation region.

17. The image sensor of claim 14, wherein the conductive layer is electrically connected to the second semiconductor pattern.

18. The image sensor of claim 12, wherein the first semiconductor pattern comprises p-type impurities.

19. An image sensor comprising:
a substrate having a first surface and a second surface opposite to each other and including a plurality of photoelectric conversion regions in a lattice structure;
an isolation region in the substrate that extends vertically from the first surface and defines a first photoelectric conversion region;
a second photoelectric conversion region spaced apart in a first direction parallel to the second surface;
a third photoelectric conversion region spaced apart in a diagonal direction with respect to the first direction;
an insulating layer between the first photoelectric conversion region and the second photoelectric conversion region and including silicon oxide or silicon nitride;
a conductive layer between the first photoelectric conversion region and the third photoelectric conversion region and including an undoped polysilicon layer; and
a color filter and a microlens on an upper portion of the second surface, wherein the isolation region comprises
a trench,
a first semiconductor pattern conformally covering an inner wall of the trench,
an insulating film conformally covering an inner wall of the first semiconductor pattern,
a second semiconductor pattern covering an inner wall of a lower portion of the insulating film and including polysilicon doped with boron (B), and
a conductive pattern comprising undoped polysilicon, covering an inner wall of an upper portion of the insulating film and an uppermost and an inner wall of the second semiconductor pattern, and configured to receive negative bias voltage, wherein
a vertical distance from the first surface to an uppermost surface of the first semiconductor pattern is substantially the same as a vertical distance from the first surface to an uppermost surface of the conductive pattern, and
a vertical distance from the first surface to an uppermost surface of the second semiconductor pattern is greater than a vertical distance from the first surface to the uppermost surface of the conductive pattern.

20. The image sensor of claim 19, wherein the conductive pattern comprises:
a first region covering an inner wall of an upper portion of the insulating film; and a second region covering an uppermost surface and an inner wall of the second semiconductor pattern, wherein
the second semiconductor pattern is not placed between the first region and the first semiconductor pattern,
the conductive pattern is electrically connected to the second semiconductor pattern through the second region, and
a thickness of the conductive pattern is 10 nanometers or less.
